(19) United States
(12) Patent Application Publication
(10) Pub. No.: US 2023/0117944 A1
(43) Pub. Date: Apr. 20, 2023

(54) BONDED SUBSTRATE AND ITS MANUFACTURING METHOD

(71) Applicants: THE JAPAN STEEL WORKS, LTD., Tokyo (JP); UNIVERSITY OF YAMANASHI, Kofu-shi (JP)

(72) Inventors: Kazuhito KISHIDA, Tokyo (JP); Shoji KAKIO, Kofu-shi (JP); Hiroaki YOKOTA, Tokyo (JP); Takuya MARUKO, Tokyo (JP); Kengo OGAWA, Tokyo (JP)

(21) Appl. No.: 17/966,879

(22) Filed: Oct. 16, 2022

(30) Foreign Application Priority Data
Oct. 18, 2021 (JP) 2021-170453

(51) Int. Cl. H03H 9/02

(52) U.S. Cl. CPC H03H 9/02551; H03H 9/02905

(57) ABSTRACT

In a bonded substrate according to an embodiment, Euler angles (φ1, θ1, ψ1) of a first quartz-crystal substrate satisfy 0°≤φ1≤2°, 123°≤θ1≤128°, and 31°≤ψ1≤44°, Euler angles (φ2, θ2, ψ2) of a second quartz-crystal substrate bonded over the first quartz-crystal substrate satisfy 83°≤φ2≤95°, 82°≤θ2≤95°, and 159°≤ψ2≤161°, and a thickness of the second quartz-crystal substrate is 0.17 to 0.19 times a wavelength of a surface acoustic wave.

### INCORPORATION BY REFERENCE

This application is based upon and claims the benefit of priority from Japanese patent application No. 2021-170453, filed on Oct. 18, 2021, the disclosure of which is incorporated herein in its entirety by reference.

### BACKGROUND

The present disclosure relates to a bonded substrate and its manufacturing method.

With the evolution of mobile communication devices such as mobile phones, there have been demands to improve performances of surface acoustic wave (SAW) filters. In a surface acoustic wave resonator constituting a part of such an SAW filter, for example, there have been demands to widen a bandwidth by improving an electro-mechanical coupling coefficient K² and to lower an absolute value of a temperature coefficient of frequency (TCF). As disclosed in Japanese Unexamined Patent Application Publication Nos. 2018-026695, 2019-004308, and 2019-145920, the inventors of the present disclosure have previously developed surface acoustic wave resonators in which a piezoelectric crystal substrate is bonded over a quartz-crystal substrate.

### SUMMARY

The inventors have found various problems in the development of surface acoustic wave resonators provided with a quartz-crystal substrate.

Other problems to be solved and novel features will become apparent from descriptions in the present specification and accompanying drawings.

In a bonded substrate according to an embodiment, Euler angles (φ1, θ1, ψ1) of a first quartz-crystal substrate satisfy 0°≤φ1≤2°, 123°≤θ1≤128°, and 31°≤ψ1≤44°, Euler angles (φ2, θ2, ψ2) of a second quartz-crystal substrate bonded over the first quartz-crystal substrate satisfy 83°≤φ2≤95°, 82°≤θ2 ≤95°, and 159°≤ψ2≤161°, and a thickness of the second quartz-crystal substrate is 0.17 to 0.19 times a wavelength of a surface acoustic wave.

According to the embodiment described above, a superior surface acoustic wave resonator can be provided.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a perspective view showing an example of a configuration of the surface acoustic wave resonator according to the first embodiment;

FIG. 2 is a graph showing propagation-direction dependence of a phase velocity of a surface acoustic wave in X-cut, Y-cut, Z-cut, and AT-cut quartz-crystal substrates QS1;

FIG. 3 is a graph showing a result of a theoretical analysis of normalized plate thickness dependence of the quartz-crystal substrate QS2 with respect to various characteristics of the surface acoustic wave resonator according to the first embodiment;

FIG. 4 is a graph showing a result of an analysis of resonance characteristics of the surface acoustic wave resonator according to the first embodiment by a simulation;

FIG. 5 is a graph showing a result of a theoretical analysis of cut angle φ1 dependence of the quartz-crystal substrate QS1 with respect to propagation attenuation of the surface acoustic wave resonator according to the first embodiment;

FIG. 6 is a graph showing a result of a theoretical analysis of cut angle θ1 dependence of the quartz-crystal substrate QS1 with respect to propagation attenuation of the surface acoustic wave resonator according to the first embodiment;

FIG. 7 is a graph showing a result of a theoretical analysis of propagation angle ψ1 dependence of the quartz-crystal substrate QS1 with respect to propagation attenuation of the surface acoustic wave resonator according to the first embodiment;

FIG. 8 is a graph showing a result of a theoretical analysis of cut angle φ2 dependence of the quartz-crystal substrate QS2 with respect to propagation attenuation of the surface acoustic wave resonator according to the first embodiment;

FIG. 9 is a graph showing a result of a theoretical analysis of cut angle θ2 dependence of the quartz-crystal substrate QS2 with respect to propagation attenuation of the surface acoustic wave resonator according to the first embodiment;

FIG. 10 is a graph showing a result of a theoretical analysis of propagation angle ψ2 dependence of the quartz-crystal substrate QS2 with respect to propagation attenuation of the surface acoustic wave resonator according to the first embodiment;

FIG. 11 is a graph showing a result of a theoretical analysis of normalized plate thickness dependence of the quartz-crystal substrate QS2 with respect to various characteristics of the surface acoustic wave resonator according to the second embodiment;

FIG. 12 is a graph showing a result of an analysis of resonance characteristics of the surface acoustic wave resonator according to the second embodiment by a simulation;

FIG. 13 is a graph showing a result of a theoretical analysis of cut angle φ1 dependence of the quartz-crystal substrate QS1 with respect to propagation attenuation of the surface acoustic wave resonator according to the second embodiment;

FIG. 14 is a graph showing a result of a theoretical analysis of cut angle θ1 dependence of the quartz-crystal substrate QS1 with respect to propagation attenuation of the surface acoustic wave resonator according to the second embodiment;

FIG. 15 is a graph showing a result of a theoretical analysis of propagation angle ψ1 dependence of the quartz-crystal substrate QS1 with respect to propagation attenuation of the surface acoustic wave resonator according to the second embodiment;

FIG. 16 is a graph showing a result of a theoretical analysis of cut angle φ2 dependence of the quartz-crystal substrate QS2 with respect to propagation attenuation of the surface acoustic wave resonator according to the second embodiment;

FIG. 17 is a graph showing a result of a theoretical analysis of cut angle θ2 dependence of the quartz-crystal substrate QS2 with respect to propagation attenuation of the surface acoustic wave resonator according to the second embodiment;

FIG. 18 is a graph showing a result of a theoretical analysis of propagation angle ψ2 dependence of the quartz-crystal substrate QS2 with respect to propagation attenuation of the surface acoustic wave resonator according to the second embodiment;

FIG. 19 is a graph showing a result of a theoretical analysis of normalized plate thickness dependence of the quartz-crystal substrate QS2 with respect to various characteristics of the surface acoustic wave resonator according to the third embodiment;

FIG. 20 is a graph showing a result of an analysis of resonance characteristics of the surface acoustic wave resonator according to the third embodiment by a simulation;

FIG. 21 is a graph showing a result of a theoretical analysis of cut angle φ1 dependence of the quartz-crystal substrate QS1 with respect to propagation attenuation of the surface acoustic wave resonator according to the third embodiment;

FIG. 22 is a graph showing a result of a theoretical analysis of cut angle θ1 dependence of the quartz-crystal substrate QS1 with respect to propagation attenuation of the surface acoustic wave resonator according to the third embodiment;

FIG. 23 is a graph showing a result of a theoretical analysis of propagation angle ψ1 dependence of the quartz-crystal substrate QS1 with respect to propagation attenuation of the surface acoustic wave resonator according to the third embodiment;

FIG. 24 is a graph showing a result of a theoretical analysis of cut angle φ2 dependence of the quartz-crystal substrate QS2 with respect to propagation attenuation of the surface acoustic wave resonator according to the third embodiment;

FIG. 25 is a graph showing a result of a theoretical analysis of cut angle θ2 dependence of the quartz-crystal substrate QS2 with respect to propagation attenuation of the surface acoustic wave resonator according to the third embodiment; and

FIG. 26 is a graph showing a result of a theoretical analysis of propagation angle ψ2 dependence of the quartz-crystal substrate QS2 with respect to propagation attenuation of the surface acoustic wave resonator according to the third embodiment.

### DESCRIPTION OF EMBODIMENTS

Hereinafter, embodiments will be specifically described with reference to the drawings. However, the present disclosure is not limited to the following embodiments. In addition, for the sake of brevity, the following descriptions and the drawings have been simplified as appropriate.

### First Embodiment

### <Configuration of Surface Acoustic Wave Resonator>

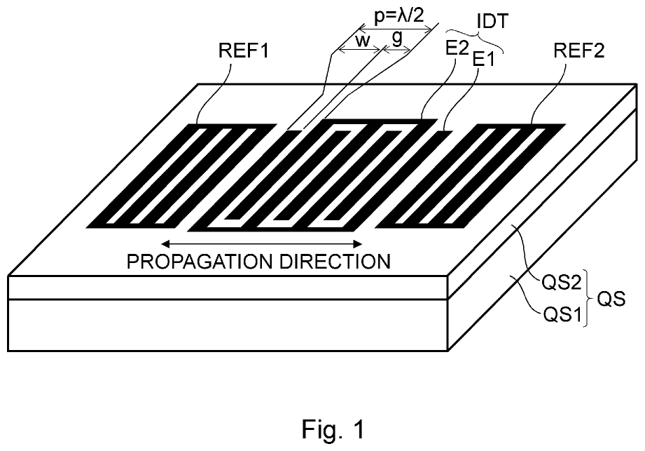

First, a configuration of a surface acoustic wave resonator according to a first embodiment will be explained with reference to FIG. 1. While the surface acoustic wave resonator according to the present embodiment is not limited to any particular application, for example, the surface acoustic wave resonator is applicable to a band rejection filter to be connected to a ceramic LC filter having gradual attenuation characteristics despite having a wide bandwidth. More specifically, by connecting a pair of the surface acoustic wave resonators according to the present embodiment to a ceramic LC filter as high-frequency side and low-frequency side band rejection filters, a band-pass filter with a wide bandwidth and steep cut-off characteristics is obtained.

As other applications of the surface acoustic wave resonator according to the present embodiment, since a high Q value is obtained, the surface acoustic wave resonator may conceivably be applied to a high-sensitivity gas/liquid sensor, a laser beam control element using an acousto-optical effect, and the like.

FIG. 1 is a perspective view showing an example of a configuration of the surface acoustic wave resonator according to the first embodiment. As shown in FIG. 1, the surface acoustic wave resonator according to the first embodiment includes a quartz-crystal substrate QS, an IDT (Interdigital Transducer) electrode IDT, and reflectors REF 1 and REF 2.

As shown in FIG. 1, the IDT electrode IDT and the reflectors REF 1 and REF 2 are formed over the quartz-crystal substrate QS. The surface acoustic wave resonator shown in FIG. 1 is a one-port surface acoustic wave resonator in which one IDT electrode IDT is disposed between two reflectors REF 1 and REF 2.

Alternatively, the surface acoustic wave resonator may be a two-port surface acoustic wave resonator in which two IDT electrodes are disposed between two reflectors REF 1 and REF 2. Furthermore, the reflectors REF 1 and REF 2 are not essential.

In the surface acoustic wave resonator according to the present embodiment, the quartz-crystal substrate QS includes two quartz-crystal substrates QS1 and QS2.

The quartz-crystal substrate (a first quartz-crystal substrate) QS1 is a single-crystal substrate made of quartz crystal (SiO₂) that is cut on a predetermined crystal plane. The quartz-crystal substrate QS1 according to the present embodiment is an AT-cut quartz-crystal substrate in which a propagation direction of a longitudinal leaky surface acoustic wave (LLSAW) is at an angle of 39° relative to an X-axis of the crystal (AT-cut 39° X-propagation).

Since the surface acoustic wave resonator according to the present embodiment uses a longitudinal leaky surface acoustic wave, hereinafter, a longitudinal leaky surface acoustic wave will be simply referred to as a surface acoustic wave.

AT-cut 39° X-propagation in the quartz-crystal substrate QS1 is represented based on Euler angles (φ1, θ1, ψ1) as Euler angles (φ1, θ1, ψ1)=(0°, 125°,)39°.

The angles φ1 and θ1 among the Euler angles indicate cut angles of the quartz-crystal substrate QS1 while the angle ψ1 indicates a propagation direction of a surface acoustic wave in the quartz-crystal substrate QS1. While the Euler angles (φ1, θ1, ψ1) of the quartz-crystal substrate QS1 respectively have allowable ranges, details will be given later.

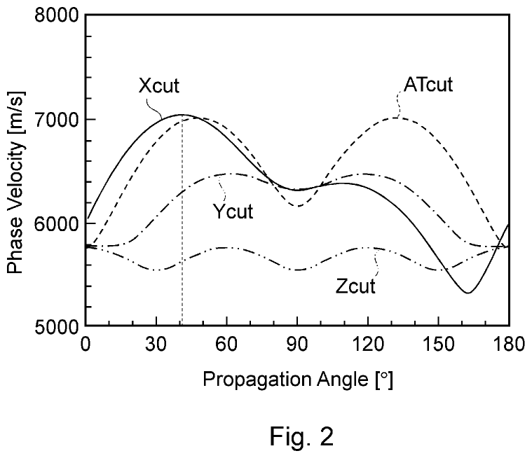

FIG. 2 is a graph showing propagation-direction dependence of a phase velocity of a surface acoustic wave in X-cut, Y-cut, Z-cut, and AT-cut quartz-crystal substrates QS1. FIG. 2 represents a result of a theoretical analysis of the phase velocity of a surface acoustic wave on a free surface of the quartz-crystal substrate QS1. In order to trap a surface acoustic wave in the quartz-crystal substrate QS2 and reduce propagation attenuation, a phase velocity of a surface acoustic wave in the quartz-crystal substrate QS1 is preferably high.

As shown in FIG. 2, a phase velocity of a surface acoustic wave in the AT-cut quartz-crystal substrate QS1 is maximized in 48° X-propagation at around 7000 m/s. As a result of a theoretical analysis, it was found that propagation attenuation is minimized and superior resonance characteristics are obtained in a combination of the AT-cut 39° X-propagation quartz-crystal substrate QS1 and the quartz-crystal substrate QS2 to be described later. As shown in FIG. 2, even in the AT-cut 39° X-propagation quartz-crystal substrate QS1, a phase velocity of a surface acoustic wave near 7000 m/s is obtained.

A thickness of the quartz-crystal substrate QS1 is, for example, 5 to 500 μm.

As shown in FIG. 1, the quartz-crystal substrate (the second quartz-crystal substrate) QS2 is bonded over the quartz-crystal substrate QS1 being a support substrate. In other words, the quartz-crystal substrate QS is a bonded substrate. The quartz-crystal substrate QS1 and the quartz-crystal substrate QS2 are bonded so as to come into direct contact with each other by, for example, surface activated bonding. The quartz-crystal substrate QS2 is an X-cut quartz-crystal substrate of which a propagation direction of a surface acoustic wave has an angle of 160° relative to the Y-axis of a crystal (X-cut 160° Y-propagation). The propagation direction of a surface acoustic wave in the quartz-crystal substrate QS1 coincides with the propagation direction of a surface acoustic wave in the quartz-crystal substrate QS2. The surface acoustic wave resonator according to the present embodiment uses a surface acoustic wave which propagates across the surface of the quartz-crystal substrate QS2.

X-cut 160° Y-propagation in the quartz-crystal substrate QS2 is represented based on Euler angles (φ2, θ2, ψ2) as Euler angles (φ2, θ2, ψ2)=(90°, 90°,) 160°. The angles φ2 and θ2 among the Euler angles indicate cut angles of the quartz-crystal substrate QS2 while the angle ψ2 indicates a propagation direction of a surface acoustic wave in the quartz-crystal substrate QS2. While the Euler angles (φ2, θ2, ψ2) of the quartz-crystal substrate QS2 also respectively have allowable ranges, details will be given later.

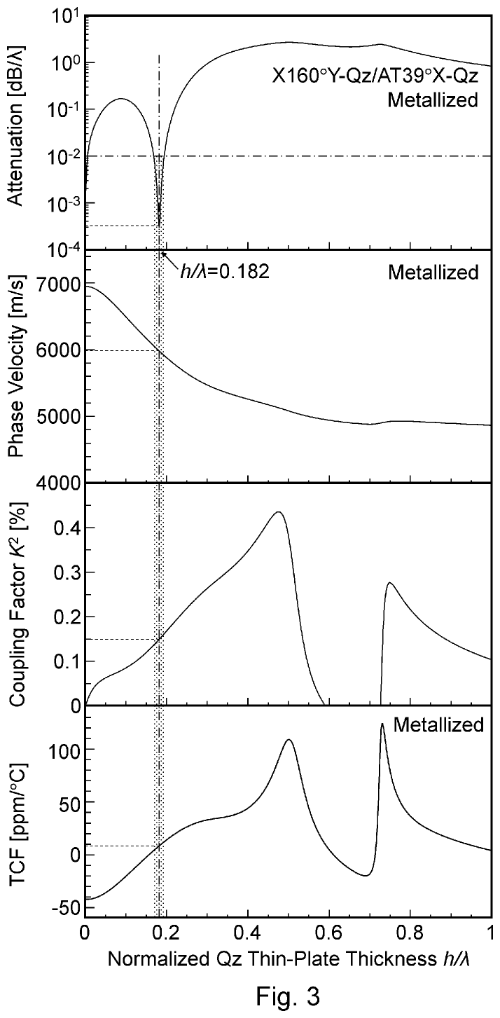

A thickness of the quartz-crystal substrate QS2 and various characteristics of the surface acoustic wave resonator according to the present embodiment will now be explained with reference to FIG. 3. FIG. 3 is a graph showing a result of a theoretical analysis of normalized plate thickness dependence of the quartz-crystal substrate QS2 with respect to various characteristics of the surface acoustic wave resonator according to the first embodiment. As described above, the surface acoustic wave resonator according to the present embodiment has a configuration in which an X-cut 160° Y-propagation quartz-crystal substrate QS2 is bonded over an AT-cut 39° X-propagation quartz-crystal substrate QS1. This configuration is denoted as X160° Y-Qz/AT39° X-Qz in FIG. 3.

An axis of abscissa in FIG. 3 is shared and represents a plate thickness h of the quartz-crystal substrate QS2 having been normalized by a wavelength λ of a surface acoustic wave or, in other words, a normalized plate thickness h/λ of the quartz-crystal substrate QS2. An axis of ordinate in FIG. 3 represents, from top to bottom, propagation attenuation, phase velocity, an electro-mechanical coupling factor K², and a temperature coefficient of frequency (TCF). As shown in FIG. 3, propagation attenuation, phase velocity, and TCF are results of a theoretical analysis on a metallized surface.

The electro-mechanical coupling factor K² is obtained using a phase velocity v_{f} on a free surface and a phase velocity vₘ on a metallized surface according to a relational expression K²=2(v_{f}−vₘ)/v_{f}.

As shown in an uppermost graph in FIG. 3, propagation attenuation of the surface acoustic wave resonator according to the present embodiment has a local minimum value when the normalized plate thickness h/λ of the quartz-crystal substrate QS2 is 0.182. As indicated by dot-hatching in FIG. 3, propagation attenuation is 0.01 dB/λ or less when the normalized plate thickness h/λ of the quartz-crystal substrate QS2 ranges from 0.169 to 0.194. Therefore, in the surface acoustic wave resonator according to the present embodiment, the thickness of the quartz-crystal substrate QS2 is configured so as to satisfy 0.17 to 0.19 times the wavelength λ of a surface acoustic wave.

As shown in a second-from-top graph in FIG. 3, a phase velocity of a surface acoustic wave in the surface acoustic wave resonator according to the present embodiment is high, at 5980 m/s, and is applicable to a filter of a high-frequency band of, for example, 3.5 GHz or more.

In addition, as shown in a third-from-top graph in FIG. 3, the electro-mechanical coupling factor K² according to the present embodiment is small, at 0.150%. When the electro-mechanical coupling factor K² is small, a passband as a band-pass filter becomes narrow. Therefore, as described above, the surface acoustic wave resonator according to the present embodiment is suitable for use as, for example, a band rejection filter.

Furthermore, as shown in a bottommost graph in FIG. 3, TCF of the surface acoustic wave resonator according to the present embodiment is small, at 8.5 ppm/° C., and is preferable.

Returning to FIG. 1, a configuration of the surface acoustic wave resonator according to the present embodiment will be explained.

The IDT electrode IDT is formed over the quartz-crystal substrate QS or, in other words, over the quartz-crystal substrate QS2 and is constituted of, for example, a metal film containing aluminum (Al) or copper (Cu) as a main component. The thickness of the metal film is, for example, several ten to several hundred nm.

As shown in FIG. 1, the IDT electrode IDT is made up of two comb-like electrodes E1 and E2. One of the electrodes E1 and E2 acts as an input electrode and the other acts as an output electrode.

Specifically, each of the electrodes E1 and E2 includes a plurality of electrode fingers (comb tooth) which are disposed parallel to each other and which are connected to one another at one end thereof. In addition, the electrodes E1 and E2 are disposed so as to oppose each other such that the electrode fingers of one of the electrodes E1 and E2 are inserted one at a time between adjacent electrode fingers of the other electrode. In other words, the electrode fingers of the electrode E1 and the electrode fingers of the electrode E2 are alternately disposed parallel to each other.

As shown in FIG. 1, the electrode fingers of the electrodes E1 and E2 extend perpendicularly with respect to the propagation direction of a surface acoustic wave on a surface of the quartz-crystal substrate QS2. In this case, a width w of each of the electrode fingers of the electrodes E1 and E2 and a gap g between one of the electrode fingers of the electrode E1 and an adjacent electrode finger of the electrode E2 are constant. In other words, a pitch p of arrangement of the electrode fingers of the IDT electrode IDT (the electrodes E1 and E2) is also constant and is equal to a sum of the width w and the gap g of the electrode fingers. In other words, p=w+g is satisfied.

In this case, the wavelength λ of a surface acoustic wave is twice the pitch p (in other words, λ=2 p) and is geometrically determined.

In addition, since a center frequency f0 of the surface acoustic wave is expressed using the phase velocity v and the wavelength λ of the surface acoustic wave as f0=v/λ, the following expression is satisfied.

f0=v/λ=v/2p=v/2(w+g)

Since the phase velocity v is determined by a cutting plane, a propagation direction, and the like of the quartz-crystal substrate QS2, reducing the pitch p enables the center frequency f0 of the surface acoustic wave to be increased.

Although a metallization ratio w/p is not limited to any particular ratio, for example, the metallization ratio w/p ranges from 0.1 to 0.9. Third-order harmonics are known not to be excited when w/p=0.5. In addition, when the pitch p is made constant (in other words, when the center frequency f0 of the surface acoustic wave is made constant), since the larger the metallization ratio w/p, the larger the width w of the electrode fingers, a lower resistance can be realized.

On the other hand, when the metallization ratio w/p exceeds 0.9, the gap g decreases, which makes it difficult to manufacture the IDT electrode IDT. In addition, when the metallization ratio w/p is smaller than 0.1, the width w decreases, which also makes it difficult to manufacture the IDT electrode IDT.

The width w of the electrode fingers of the IDT electrode IDT (the electrodes E1 and E2) is, for example, 0.2 to 1.5 μm.

While the number of electrode fingers of the electrode E1 is larger than the number of electrode fingers of the electrode E2 by one in the example shown in FIG. 1, the numbers of electrode fingers may be the same. In addition, the numbers of electrode fingers of the electrodes E1 and E2 are appropriately set. Furthermore, a configuration may be adopted in which two or more electrode fingers of one of the electrodes E1 and E2 are inserted between adjacent electrode fingers of the other of the electrodes E1 and E2.

The reflectors REF 1 and REF 2 are formed by, for example, the same metal film as the IDT electrode IDT.

As shown in FIG. 1, each of the reflectors REF 1 and REF 2 is constituted of a plurality of strips which are disposed parallel to each other and which are connected to one another at both ends thereof. The strips are disposed at the same pitch p as that of the electrode fingers of the electrodes E1 and E2 and are disposed in parallel with the electrode fingers of the electrodes E1 and E2. Since a surface acoustic wave excited by the IDT electrode IDT is reflected by the reflectors REF1 and REF2 and becomes a standing wave, a surface acoustic wave resonator having a high Q value and low loss is obtained.

In addition, since the surface acoustic wave resonator according to the first embodiment has a large reflection coefficient, the number of reflectors can be reduced and a filter area can be downsized.

After the quartz-crystal substrate QS2 is bonded over the quartz-crystal substrate QS1, the IDT electrode IDT and the reflectors REF1 and REF2 are formed over the quartz-crystal substrate QS2.

### <Analysis of Resonance Characteristics by Simulation>

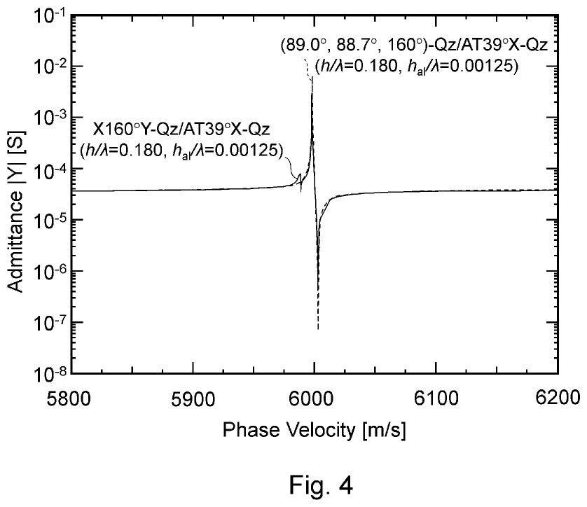

Next, a result of an analysis of resonance characteristics of the surface acoustic wave resonator according to the present embodiment by a simulation will be described with reference to FIG. 4. FIG. 4 is a graph showing a result of an analysis of resonance characteristics of the surface acoustic wave resonator according to the first embodiment by a simulation. An axis of abscissa represents a phase velocity (m/s) and an axis of ordinate represents admittance (S). The phase velocity v is a product of the wavelength λ of a surface acoustic wave multiplied by frequency f.

In FIG. 4, a result of an analysis of a surface acoustic wave resonator in which an X-cut 160° Y-propagation quartz-crystal substrate QS2 or, in other words, the quartz-crystal substrate QS2 with Euler angles (φ2, θ2, ψ2)=(90°, 90°, 160°) is bonded over an AT-cut 39° X-propagation quartz-crystal substrate QS1 is indicated by a solid line. This configuration is denoted as X160° Y-Qz/AT39° X-Qz in FIG. 4.

In addition, in FIG. 4, a result of an analysis of a surface acoustic wave resonator in which the quartz-crystal substrate QS2 with Euler angles (φ2, θ2, ψ2)=(89.0°, 88.7°, 160°) is bonded over the AT-cut 39° X-propagation quartz-crystal substrate QS1 is indicated by a dashed line. In other words, this is a configuration in which the cut angle φ2 of the quartz-crystal substrate QS2 deviates from an X-cut by 1.0° and the cut angle θ2 of the quartz-crystal substrate QS2 deviates from an X-cut by 1.3°. This configuration is denoted as (89.0°, 88.7°, 160°)-Qz/AT39° X-Qz in FIG. 4.

With respect to the surface acoustic wave resonator described above, a finite element method (FEM) analysis of resonance characteristics was performed using analysis software Femtet manufactured by Murata Software Co., Ltd. The wavelength λ (=2 p) of a surface acoustic wave was set to 8 μm and the thickness of the support substrate was set to 10 λ. In addition, as shown in FIG. 3, the normalized plate thickness h/λ of the quartz-crystal substrate QS2 was set to 0.180 at which propagation attenuation decreases.

It was assumed that the IDT electrode IDT shown in FIG. 1 is made of an aluminum (Al) film with a film thickness of 0.01 μm (=0.00125 λ) and has an infinite periodic structure. In addition, a perfect matched layer (PML) was set on a bottom surface of the IDT electrode. The metallization ratio w/p was set to 0.5. In addition, a sinusoidal AC voltage of ±1 V was applied to the IDT electrode IDT. Dielectric loss and mechanical loss of each material were not taken into consideration.

With the surface acoustic wave resonator of X160° Y-Qz/AT39° X-Qz indicated by the solid line in FIG. 4, an admittance ratio was 75 dB, a resonant quality factor was 46900, and an antiresonant quality factor was 46900, which were all high values. Moreover, a specific bandwidth was 0.070%.

With the surface acoustic wave resonator of (89.0°, 88.7°, 160°)-Qz/AT39° X-Qz indicated by the dashed line in FIG. 4, the admittance ratio was 101 dB, the resonant quality factor was 107000, and the antiresonant quality factor was 375000, which were all even higher values. Moreover, the specific bandwidth was 0.083%.

As described above, in a surface acoustic wave resonator in which the X-cut 160° Y-propagation quartz-crystal substrate QS2 having a normalized plate thickness h/λ of 0.18 is bonded over the AT-cut 39° X-propagation quartz-crystal substrate QS1, superior resonance characteristics which cannot be obtained with a stand-alone quartz-crystal substrate are obtained.

In addition, by giving the quartz-crystal substrate QS2 the cut angle φ2=89.0° and the cut angle θ2=88.7° so that the quartz-crystal substrate QS2 is slightly deviated from an X-cut, even more superior resonance characteristics are obtained.

### <Allowable Range of Euler Angles (φ1, θ1, ψ1) of Quartz-crystal Substrate QS1>

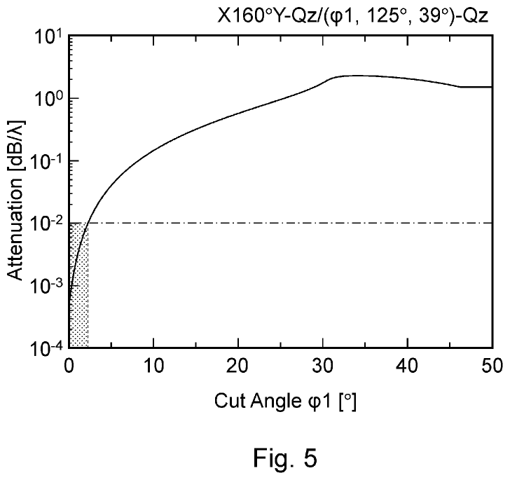

Next, an allowable range of the Euler angles (φ1, θ1, ψ1) of the quartz-crystal substrate QS1 will be explained with reference to FIGS. 5 to 7.

FIG. 5 is a graph showing a result of a theoretical analysis of cut angle φ1 dependence of the quartz-crystal substrate QS1 with respect to propagation attenuation of the surface acoustic wave resonator according to the first embodiment.

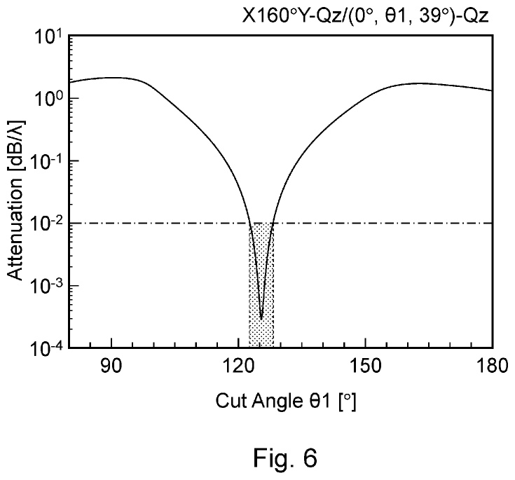

FIG. 6 is a graph showing a result of a theoretical analysis of cut angle θ1 dependence of the quartz-crystal substrate QS1 with respect to propagation attenuation of the surface acoustic wave resonator according to the first embodiment.

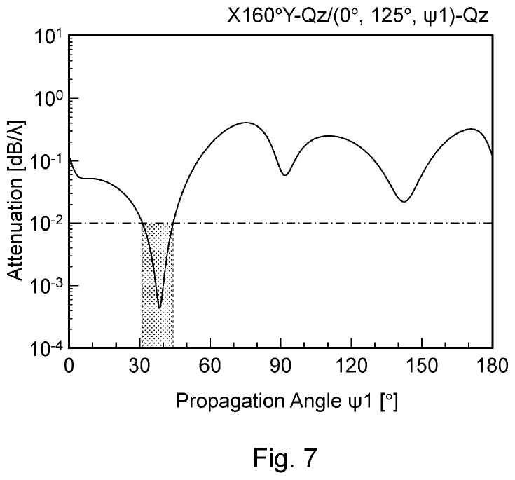

FIG. 7 is a graph showing a result of a theoretical analysis of propagation angle ψ1 dependence of the quartz-crystal substrate QS1 with respect to propagation attenuation of the surface acoustic wave resonator according to the first embodiment.

In FIGS. 5 to 7, the quartz-crystal substrate QS2 is an X-cut 160° Y-propagation quartz-crystal substrate. The normalized plate thickness h/λ of the quartz-crystal substrate QS2 was respectively set to 0.182 in FIG. 3 at which propagation attenuation is locally minimized.

As shown in FIG. 5, when changing the cut angle φ1 of the quartz-crystal substrate QS1, the cut angle θ1 was fixed to 125° and the propagation angle ψ1 was fixed to 39°.

As shown in FIG. 6, when changing the cut angle θ1 of the quartz-crystal substrate QS1, the cut angle φ1 was fixed to 0° and the propagation angle ψ1 was fixed to 39°.

As shown in FIG. 7, when changing the propagation angle ψ1 of the quartz-crystal substrate QS1, the cut angle φ1 was fixed to 0° and the cut angle θ1 was fixed to 125°.

As indicated by dot-hatching in FIG. 5, in the surface acoustic wave resonator according to the present embodiment, propagation attenuation is 0.01 dB/λ or less when the cut angle φ1 of the quartz-crystal substrate QS1 ranges from 0 to 2.2°. Therefore, in the surface acoustic wave resonator according to the present embodiment, the cut angle φ1 of the quartz-crystal substrate QS1 is configured so as to satisfy 0°≤φ1≤2°. The cut angle φ1 of the quartz-crystal substrate QS1 preferably satisfies 0°≤φ1≤1°. Note that a solution is only obtained in a range of the cut angle φ1 shown in FIG. 5.

As indicated by dot-hatching in FIG. 6, in the surface acoustic wave resonator according to the present embodiment, propagation attenuation is 0.01 dB/λ or less when the cut angle θ1 of the quartz-crystal substrate QS1 ranges from 122.7 to 128.1°. Therefore, in the surface acoustic wave resonator according to the present embodiment, the cut angle θ1 of the quartz-crystal substrate QS1 is configured so as to satisfy 123°≤θ1≤128°. The cut angle θ1 of the quartz-crystal substrate QS1 preferably satisfies 124°≤θ1≤127°.

As indicated by dot-hatching in FIG. 7, in the surface acoustic wave resonator according to the present embodiment, propagation attenuation is 0.01 dB/λ or less when the propagation angle ψ1 of the quartz-crystal substrate QS1 ranges from 31.3 to 44.2°. Therefore, in the surface acoustic wave resonator according to the present embodiment, the propagation angle ψ1 of the quartz-crystal substrate QS1 is configured so as to satisfy 31°≤ψ1≤42°. The propagation angle ψ1 of the quartz-crystal substrate QS1 preferably satisfies 37°≤ψ1≤41° and more preferably satisfies 38°≤ψ1≤40°.

### <Allowable Range of Euler Angles (φ2, θ2, ψ2) of Quartz-crystal Substrate QS2>

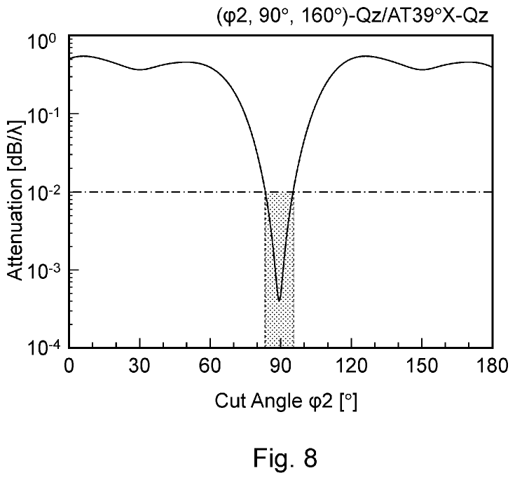

Next, an allowable range of the Euler angles (φ2, θ2, ψ2) of the quartz-crystal substrate QS2 will be explained with reference to FIGS. 8 to 10.

FIG. 8 is a graph showing a result of a theoretical analysis of cut angle φ2 dependence of the quartz-crystal substrate QS2 with respect to propagation attenuation of the surface acoustic wave resonator according to the first embodiment.

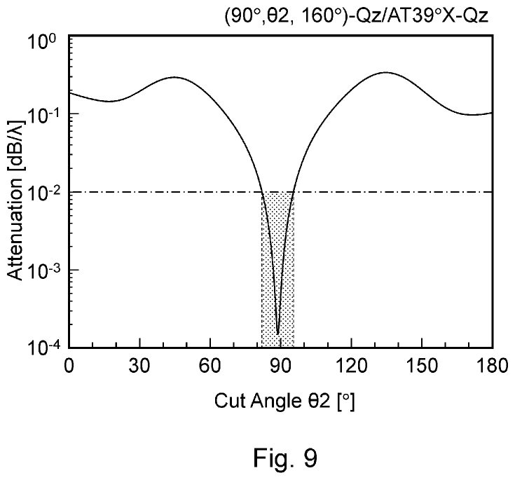

FIG. 9 is a graph showing a result of a theoretical analysis of cut angle θ2 dependence of the quartz-crystal substrate QS2 with respect to propagation attenuation of the surface acoustic wave resonator according to the first embodiment.

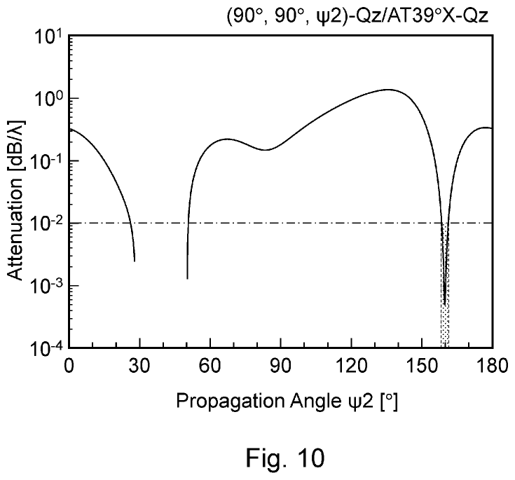

FIG. 10 is a graph showing a result of a theoretical analysis of propagation angle ψ2 dependence of the quartz-crystal substrate QS2 with respect to propagation attenuation of the surface acoustic wave resonator according to the first embodiment.

In FIGS. 8 to 10, the quartz-crystal substrate QS1 is an AT-cut 39° X-propagation quartz-crystal substrate. The normalized plate thickness h/λ of the quartz-crystal substrate QS2 was respectively set to 0.182 in FIG. 3 at which propagation attenuation is locally minimized.

As shown in FIG. 8, when changing the cut angle φ2 of the quartz-crystal substrate QS2, the cut angle θ2 was fixed to 90° and the propagation angle ψ2 was fixed to 160°.

As shown in FIG. 9, when changing the cut angle θ2 of the quartz-crystal substrate QS2, the cut angle φ2 was fixed to 90° and the propagation angle ψ2 was fixed to 160°.

As shown in FIG. 10, when changing the propagation angle ψ2 of the quartz-crystal substrate QS2, the cut angle φ2 was fixed to 90° and the cut angle θ2 was fixed to 90°.

As indicated by dot-hatching in FIG. 8, in the surface acoustic wave resonator according to the present embodiment, propagation attenuation is 0.01 dB/λ or less when the cut angle φ2 of the quartz-crystal substrate QS2 ranges from 83.4 to 95.2°. Therefore, in the surface acoustic wave resonator according to the present embodiment, the cut angle φ2 of the quartz-crystal substrate QS2 is configured so as to satisfy 83°≤φ2≤95°. The cut angle φ2 of the quartz-crystal substrate QS2 preferably satisfies 88°≤φ2≤90°.

As indicated by dot-hatching in FIG. 9, in the surface acoustic wave resonator according to the present embodiment, propagation attenuation is 0.01 dB/λ or less when the cut angle θ2 of the quartz-crystal substrate QS2 ranges from 82.1 to 95.3°. Therefore, in the surface acoustic wave resonator according to the present embodiment, the cut angle θ2 of the quartz-crystal substrate QS2 is configured so as to satisfy 82°≤θ2≤95°. The cut angle θ2 of the quartz-crystal substrate QS2 preferably satisfies 87°≤θ2≤90°.

As indicated by dot-hatching in FIG. 10, in the surface acoustic wave resonator according to the present embodiment, propagation attenuation is 0.01 dB/λ or less when the propagation angle ψ2 of the quartz-crystal substrate QS2 ranges from 158.7 to 161.4°. Therefore, in the surface acoustic wave resonator according to the present embodiment, the propagation angle ψ2 of the quartz-crystal substrate QS2 is configured so as to satisfy 159°≤ψ2≤161°.

### Second Embodiment

Next, a configuration of a surface acoustic wave resonator according to a second embodiment will be explained. In a similar manner to the surface acoustic wave resonator according to the first embodiment, the configuration of the surface acoustic wave resonator according to the second embodiment is also as shown in FIG. 1.

In the surface acoustic wave resonator according to the present embodiment, the quartz-crystal substrate QS1 is an X-cut quartz-crystal substrate of which a propagation direction of a surface acoustic wave has an angle of 41° relative to the Y-axis of a crystal (X-cut 41° Y-propagation).

In this case, X-cut 41° Y-propagation in the quartz-crystal substrate QS1 is represented based on Euler angles (φ1, θ1, ψ1) as Euler angles (φ1, θ1, ψ1)=(90°, 90°, 41°). While the Euler angles (φ1, θ1, ψ1) of the quartz-crystal substrate QS1 respectively have allowable ranges, details will be given later.

As shown in FIG. 2, a phase velocity of a surface acoustic wave of the X-cut quartz-crystal substrate QS1 is maximized in 41° Y-propagation at around 7000 m/s. As a result of a theoretical analysis, it was found that propagation attenuation is minimized and superior resonance characteristics are obtained in a combination of the X-cut 41° Y-propagation quartz-crystal substrate QS1 with maximized phase velocity and the quartz-crystal substrate QS2 to be described later.

Furthermore, in the surface acoustic wave resonator according to the present embodiment, the quartz-crystal substrate QS2 is an X-cut quartz-crystal substrate of which a propagation direction of a surface acoustic wave has an angle of 59° relative to the Y-axis of a crystal (X-cut 59° Y-propagation).

In this case, X-cut 59° Y-propagation in the quartz-crystal substrate QS2 is represented based on Euler angles (φ2, θ2, ψ2) as Euler angles (φ2, θ2, ψ2)=(90°, 90°,)59°. While the Euler angles (φ2, θ2, ψ2) of the quartz-crystal substrate QS2 also respectively have allowable ranges, details will be given later.

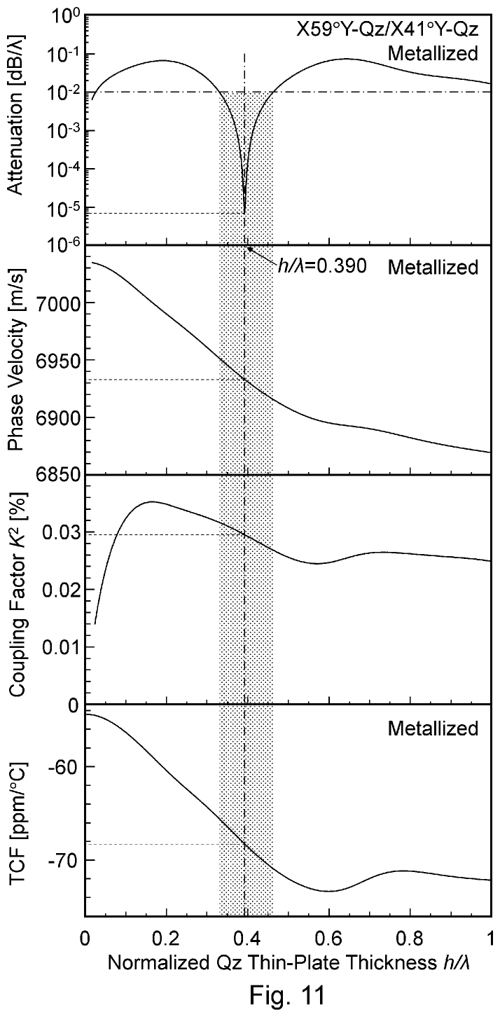

A thickness of the quartz-crystal substrate QS2 and various characteristics of the surface acoustic wave resonator according to the present embodiment will now be explained with reference to FIG. 11. FIG. 11 is a graph showing a result of a theoretical analysis of normalized plate thickness dependence of the quartz-crystal substrate QS2 with respect to various characteristics of the surface acoustic wave resonator according to the second embodiment. FIG. 11 corresponds to FIG. 3 in the first embodiment. As described above, the surface acoustic wave resonator according to the present embodiment has a configuration in which an X-cut 59° Y-propagation quartz-crystal substrate QS2 is bonded over an X-cut 41° Y-propagation quartz-crystal substrate QS1. This configuration is denoted as X59° Y-Qz/X41° Y-Qz in FIG. 11.

An axis of abscissa in FIG. 11 is shared and represents a plate thickness h of the quartz-crystal substrate QS2 having been normalized by a wavelength λ of a surface acoustic wave or, in other words, a normalized plate thickness h/λ of the quartz-crystal substrate QS2. An axis of ordinate in FIG. 11 represents, from top to bottom, propagation attenuation, phase velocity, an electro-mechanical coupling factor K², and a TCF. As shown in FIG. 11, propagation attenuation, phase velocity, and TCF are results of a theoretical analysis on a metallized surface.

As shown in an uppermost graph in FIG. 11, propagation attenuation of the surface acoustic wave resonator according to the present embodiment has a local minimum value when the normalized plate thickness h/λ of the quartz-crystal substrate QS2 is 0.390. As indicated by dot-hatching in FIG. 11, propagation attenuation is 0.01 dB/λ or less when the normalized plate thickness h/λ of the quartz-crystal substrate QS2 ranges from 0.331 to 0.462. Therefore, in the surface acoustic wave resonator according to the present embodiment, the thickness of the quartz-crystal substrate QS2 is configured so as to satisfy 0.33 to 0.46 times the wavelength λ of a surface acoustic wave. The thickness of the quartz-crystal substrate QS2 is preferably 0.35 to 0.43 times the wavelength λ of a surface acoustic wave and more preferably 0.37 to 0.41 times the wavelength λ of the surface acoustic wave.

As shown in a second-from-top graph in FIG. 11, a phase velocity of a surface acoustic wave in the surface acoustic wave resonator according to the present embodiment is high, at 6930 m/s, and is applicable to a filter of a high-frequency band of, for example, 3.5 GHz or more.

In addition, as shown in a third-from-top graph in FIG. 11, the electro-mechanical coupling factor K² according to the present embodiment is small, at 0.030%. When the electro-mechanical coupling factor K² is small, a passband as a band-pass filter becomes narrow. Therefore, as described above, the surface acoustic wave resonator according to the present embodiment is suitable for use as, for example, a band rejection filter.

Furthermore, as shown in a bottommost graph in FIG. 11, TCF of the surface acoustic wave resonator according to the present embodiment is slightly large, at −68.1 ppm/° C.

### <Analysis of Resonance Characteristics by Simulation>

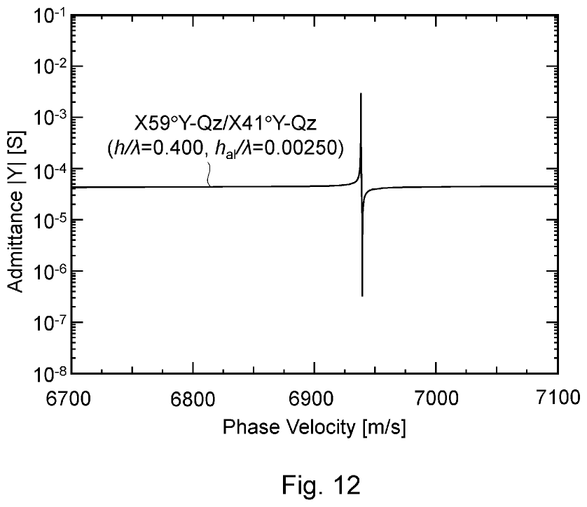

Next, a result of an analysis of resonance characteristics of the surface acoustic wave resonator according to the present embodiment by a simulation will be described with reference to FIG. 12. FIG. 12 is a graph showing a result of an analysis of resonance characteristics of the surface acoustic wave resonator according to the second embodiment by a simulation. FIG. 12 corresponds to FIG. 4 in the first embodiment and, in FIG. 12, an axis of abscissa represents a phase velocity (m/s) and an axis of ordinate represents admittance (S).

In FIG. 12, a result of an analysis of a surface acoustic wave resonator in which an X-cut 59° Y-propagation quartz-crystal substrate QS2 is bonded over an X-cut 41° Y-propagation quartz-crystal substrate QS1 is indicated by a solid line. This configuration is denoted as X59° Y-Qz/X41° Y-Qz in FIG. 12.

With respect to the surface acoustic wave resonator described above, a finite element method (FEM) analysis of resonance characteristics was performed using analysis software Femtet manufactured by Murata Software Co., Ltd. The wavelength λ (=2 p) of a surface acoustic wave was set to 8 μm and the thickness of the support substrate was set to 10 λ. In addition, as shown in FIG. 11, the normalized plate thickness h/λ of the quartz-crystal substrate QS2 was set to 0.400 at which propagation attenuation decreases.

It was assumed that the IDT electrode IDT shown in FIG. 1 is made of an aluminum (Al) film with a film thickness of 0.02 μm (=0.00250 λ) and has an infinite periodic structure. In addition, a perfect matched layer (PML) was set on a bottom surface of the IDT electrode. The metallization ratio w/p was set to 0.5. In addition, a sinusoidal AC voltage of ±1 V was applied to the IDT electrode IDT. Dielectric loss and mechanical loss of each material were not taken into consideration.

With the surface acoustic wave resonator of X59° Y-Qz/X41° Y-Qz shown in FIG. 12, an admittance ratio was 78 dB, a resonant quality factor was 217000, and an antiresonant quality factor was 289000, which were all high values. Moreover, the specific bandwidth was 0.016%.

As described above, in a surface acoustic wave resonator in which the X-cut 59° Y-propagation quartz-crystal substrate QS2 having a normalized plate thickness h/λ of 0.4 is bonded over the X-cut 41° Y-propagation quartz-crystal substrate QS1, superior resonance characteristics which cannot be obtained with a stand-alone quartz-crystal substrate are obtained.

### <Allowable Range of Euler Angles (φ1, θ1, ψ1) of Quartz-crystal Substrate QS1>

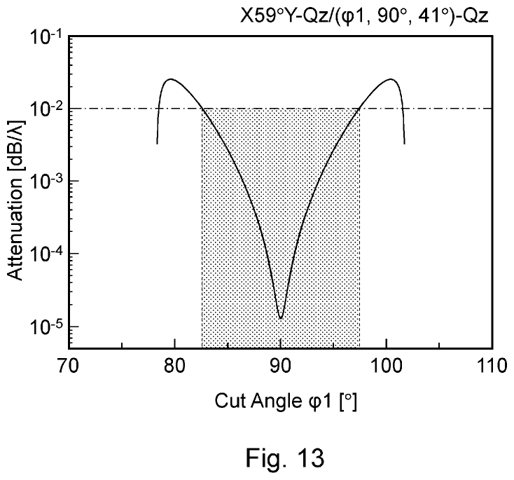

Next, an allowable range of the Euler angles (φ1, θ1, ψ1) of the quartz-crystal substrate QS1 will be explained with reference to FIGS. 13 to 15.

FIG. 13 is a graph showing a result of a theoretical analysis of cut angle φ1 dependence of the quartz-crystal substrate QS1 with respect to propagation attenuation of the surface acoustic wave resonator according to the second embodiment.

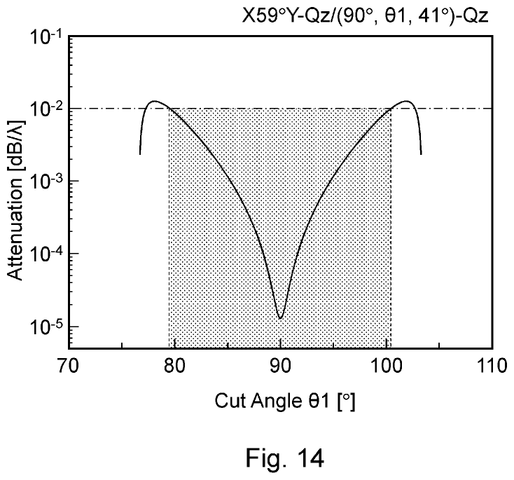

FIG. 14 is a graph showing a result of a theoretical analysis of cut angle θ1 dependence of the quartz-crystal substrate QS1 with respect to propagation attenuation of the surface acoustic wave resonator according to the second embodiment.

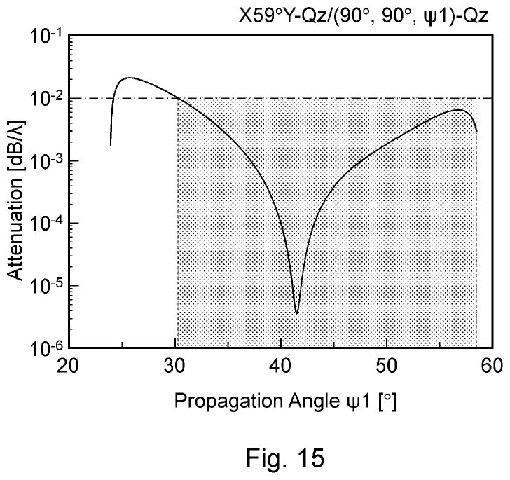

FIG. 15 is a graph showing a result of a theoretical analysis of propagation angle ψ1 dependence of the quartz-crystal substrate QS1 with respect to propagation attenuation of the surface acoustic wave resonator according to the second embodiment.

In FIGS. 13 to 15, the quartz-crystal substrate QS2 is an X-cut 59° Y-propagation quartz-crystal substrate. The normalized plate thickness h/λ of the quartz-crystal substrate QS2 was respectively set to 0.390 in FIG. 11 at which propagation attenuation is locally minimized.

As shown in FIG. 13, when changing the cut angle φ1 of the quartz-crystal substrate QS1, the cut angle θ1 was fixed to 90° and the propagation angle ψ1 was fixed to 41°.

As shown in FIG. 14, when changing the cut angle θ1 of the quartz-crystal substrate QS1, the cut angle φ1 was fixed to 90° and the propagation angle ψ1 was fixed to 41°.

As shown in FIG. 15, when changing the propagation angle ψ1 of the quartz-crystal substrate QS1, the cut angle φ1 was fixed to 90° and the cut angle θ1 was fixed to 90°.

As indicated by dot-hatching in FIG. 13, in the surface acoustic wave resonator according to the present embodiment, propagation attenuation is 0.01 dB/λ or less when the cut angle φ1 of the quartz-crystal substrate QS1 ranges from 82.7 to 97.3°. Therefore, in the surface acoustic wave resonator according to the present embodiment, the cut angle φ1 of the quartz-crystal substrate QS1 is configured so as to satisfy 83°≤φ1≤97°. Note that a solution is only obtained in a range of a curved line shown in FIG. 13. The cut angle φ1 of the quartz-crystal substrate QS1 preferably satisfies 85°≤φ1≤95° and more preferably satisfies 87°≤φ1≤93°.

As indicated by dot-hatching in FIG. 14, in the surface acoustic wave resonator according to the present embodiment, propagation attenuation is 0.01 dB/λ or less when the cut angle θ1 of the quartz-crystal substrate QS1 ranges from 79.6 to 100.4°. Therefore, in the surface acoustic wave resonator according to the present embodiment, the cut angle θ1 of the quartz-crystal substrate QS1 is configured so as to satisfy 80°≤θ1≤100°. Note that a solution is only obtained in a range of a curved line shown in FIG. 14. The cut angle θ1 of the quartz-crystal substrate QS1 preferably satisfies 85°≤θ1≤95° and more preferably satisfies 87°≤θ1≤93°.

As indicated by dot-hatching in FIG. 15, in the surface acoustic wave resonator according to the present embodiment, propagation attenuation is 0.01 dB/λ or less when the propagation angle ψ1 of the quartz-crystal substrate QS1 ranges from 30.3 to 58.5°. Therefore, in the surface acoustic wave resonator according to the present embodiment, the propagation angle ψ1 of the quartz-crystal substrate QS1 is configured so as to satisfy 30°≤ψ1≤59°. Note that a solution is only obtained in a range of a curved line shown in FIG. 15. The propagation angle ψ1 of the quartz-crystal substrate QS1 preferably satisfies 36°≤ψ1≤46° and more preferably satisfies 38°≤ψ1≤44°.

### <Allowable Range of Euler Angles (φ2, θ2, ψ2) of Quartz-crystal Substrate QS2>

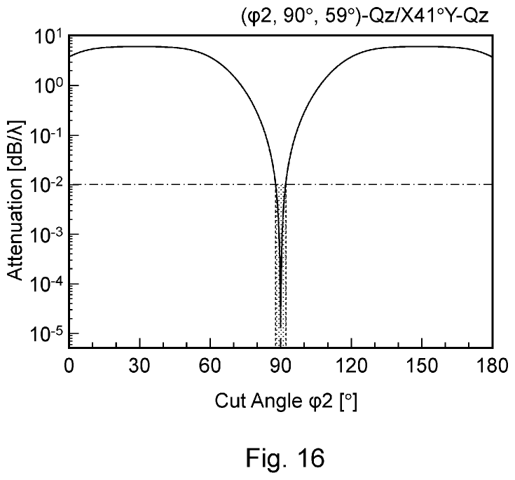

Next, an allowable range of the Euler angles (φ2, θ2, ψ2) of the quartz-crystal substrate QS2 will be explained with reference to FIGS. 16 to 18.

FIG. 16 is a graph showing a result of a theoretical analysis of cut angle φ2 dependence of the quartz-crystal substrate QS2 with respect to propagation attenuation of the surface acoustic wave resonator according to the second embodiment.

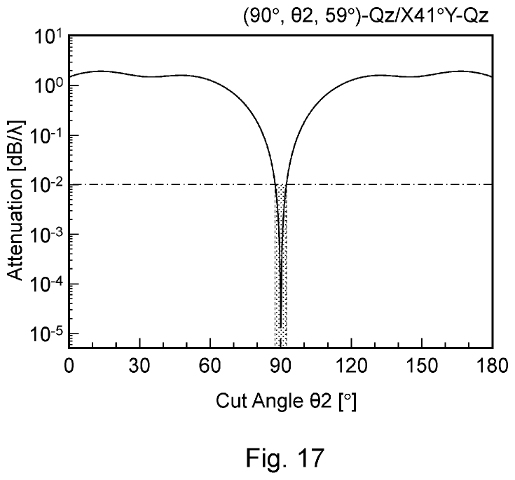

FIG. 17 is a graph showing a result of a theoretical analysis of cut angle θ2 dependence of the quartz-crystal substrate QS2 with respect to propagation attenuation of the surface acoustic wave resonator according to the second embodiment.

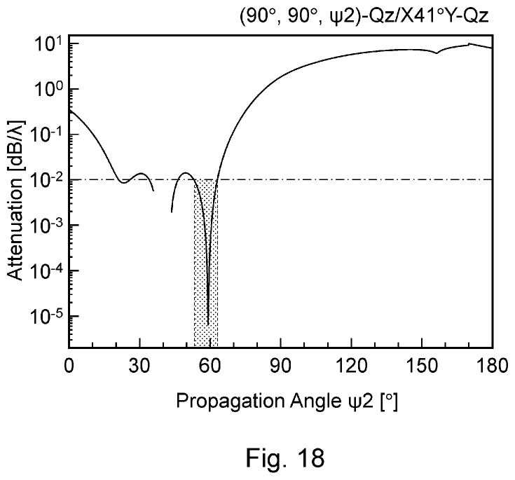

FIG. 18 is a graph showing a result of a theoretical analysis of propagation angle ψ2 dependence of the quartz-crystal substrate QS2 with respect to propagation attenuation of the surface acoustic wave resonator according to the second embodiment.

In FIGS. 16 to 18, the quartz-crystal substrate QS1 is an X-cut 41° Y-propagation quartz-crystal substrate. The normalized plate thickness h/λ of the quartz-crystal substrate QS2 was respectively set to 0.390 in FIG. 11 at which propagation attenuation is locally minimized.

As shown in FIG. 16, when changing the cut angle φ2 of the quartz-crystal substrate QS2, the cut angle θ2 was fixed to 90° and the propagation angle ψ2 was fixed to 59°.

As shown in FIG. 17, when changing the cut angle θ2 of the quartz-crystal substrate QS2, the cut angle φ2 was fixed to 90° and the propagation angle ψ2 was fixed to 59°.

As shown in FIG. 18, when changing the propagation angle ψ2 of the quartz-crystal substrate QS2, the cut angle φ2 was fixed to 90° and the cut angle θ2 was fixed to 90°.

As indicated by dot-hatching in FIG. 16, in the surface acoustic wave resonator according to the present embodiment, propagation attenuation is 0.01 dB/λ or less when the cut angle φ2 of the quartz-crystal substrate QS2 ranges from 87.9 to 92.1°. Therefore, in the surface acoustic wave resonator according to the present embodiment, the cut angle φ2 of the quartz-crystal substrate QS2 is configured so as to satisfy 88°≤φ2≤92°. The cut angle φ2 of the quartz-crystal substrate QS2 preferably satisfies 89°≤φ2≤91°.

As indicated by dot-hatching in FIG. 17, in the surface acoustic wave resonator according to the present embodiment, propagation attenuation is 0.01 dB/λ or less when the cut angle θ2 of the quartz-crystal substrate QS2 ranges from 87.7 to 92.3°. Therefore, in the surface acoustic wave resonator according to the present embodiment, the cut angle θ2 of the quartz-crystal substrate QS2 is configured so as to satisfy 88°≤θ2≤92°. The cut angle θ2 of the quartz-crystal substrate QS2 preferably satisfies 89°≤θ2≤91°.

As indicated by dot-hatching in FIG. 18, in the surface acoustic wave resonator according to the present embodiment, propagation attenuation is 0.01 dB/λ or less when the propagation angle ψ2 of the quartz-crystal substrate QS2 ranges from 53.1 to 63.0°. Therefore, in the surface acoustic wave resonator according to the present embodiment, the propagation angle ψ2 of the quartz-crystal substrate QS2 is configured so as to satisfy 53°≤ψ2≤63°. The propagation angle ψ2 of the quartz-crystal substrate QS2 preferably satisfies 57°≤ψ2≤61°. Note that a solution cannot be obtained in a range shown in FIG. 18 where a curved line is broken.

The configuration is otherwise the same as the surface acoustic wave resonator according to the first embodiment.

### Third Embodiment

Next, a configuration of a surface acoustic wave resonator according to a third embodiment will be explained. In a similar manner to the surface acoustic wave resonator according to the first embodiment, the configuration of the surface acoustic wave resonator according to the third embodiment is also as shown in FIG. 1.

In a similar manner to the second embodiment, in the surface acoustic wave resonator according to the present embodiment, the quartz-crystal substrate QS1 is a 41° Y-propagation quartz-crystal substrate in which phase velocity is maximized in an X-cut.

In this case, X-cut 41° Y-propagation in the quartz-crystal substrate QS1 is represented based on Euler angles (φ1, θ1, ψ1) as Euler angles (φ1, θ1, ψ1)=(90°, 90°, 41°). While the Euler angles (φ1, θ1, ψ1) of the quartz-crystal substrate QS1 respectively have allowable ranges, details will be given later.

Furthermore, in the surface acoustic wave resonator according to the present embodiment, the quartz-crystal substrate QS2 is an X-cut quartz-crystal substrate of which a propagation direction of a surface acoustic wave has an angle of 0° relative to the Y-axis of a crystal (X-cut 0° Y-propagation).

In this case, X-cut 0° Y-propagation in the quartz-crystal substrate QS2 is represented based on Euler angles (φ2, θ2, ψ2) as Euler angles (φ2, θ2, ψ2)=(90°, 90°, 0°). While the Euler angles (φ2, θ2, ψ2) of the quartz-crystal substrate QS2 also respectively have allowable ranges, details will be given later.

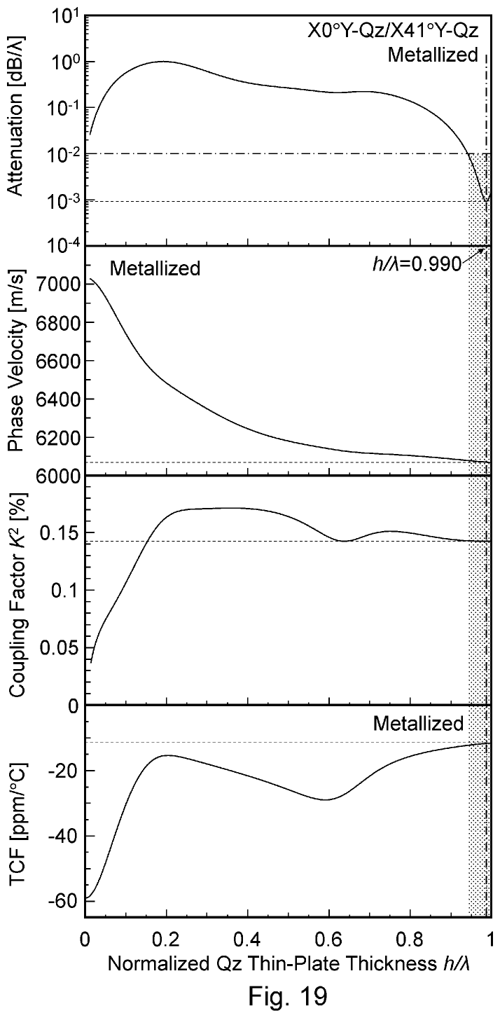

A thickness of the quartz-crystal substrate QS2 and various characteristics of the surface acoustic wave resonator according to the present embodiment will now be explained with reference to FIG. 19. FIG. 19 is a graph showing a result of a theoretical analysis of normalized plate thickness dependence of the quartz-crystal substrate QS2 with respect to various characteristics of the surface acoustic wave resonator according to the third embodiment. FIG. 19 corresponds to FIG. 3 in the first embodiment. As described above, the surface acoustic wave resonator according to the present embodiment has a configuration in which an X-cut 0° Y-propagation quartz-crystal substrate QS2 is bonded over an X-cut 41° Y-propagation quartz-crystal substrate QS1. This configuration is denoted as X0° Y-Qz/X41° Y-Qz in FIG. 19.

An axis of abscissa in FIG. 19 is shared and represents a plate thickness h of the quartz-crystal substrate QS2 having been normalized by a wavelength λ of a surface acoustic wave or, in other words, a normalized plate thickness h/λ of the quartz-crystal substrate QS2. An axis of ordinate in FIG. 19 represents, from top to bottom, propagation attenuation, phase velocity, an electro-mechanical coupling factor K², and a TCF. As shown in FIG. 19, propagation attenuation, phase velocity, and TCF are results of a theoretical analysis on a metallized surface.

As shown in an uppermost graph in FIG. 19, propagation attenuation of the surface acoustic wave resonator according to the present embodiment has a local minimum value when the normalized plate thickness h/λ of the quartz-crystal substrate QS2 is 0.990. As indicated by dot-hatching in FIG. 19, propagation attenuation is 0.01 dB/λ or less when the normalized plate thickness h/λ of the quartz-crystal substrate QS2 ranges from 0.942 to 1.036. Therefore, in the surface acoustic wave resonator according to the present embodiment, the thickness of the quartz-crystal substrate QS2 is configured so as to satisfy 0.94 to 1.04 times the wavelength λ of a surface acoustic wave. The thickness of the quartz-crystal substrate QS2 is preferably 0.96 to 1.02 times the wavelength λ of a surface acoustic wave and more preferably 0.98 to 1.00 times the wavelength λ of the surface acoustic wave.

As shown in a second-from-top graph in FIG. 19, a phase velocity of a surface acoustic wave in the surface acoustic wave resonator according to the present embodiment is high, at 6070 m/s, and is applicable to a filter of a high-frequency band of, for example, 3.5 GHz or more.

In addition, as shown in a third-from-top graph in FIG. 19, the electro-mechanical coupling factor K² according to the present embodiment is small, at 0.143%. When the electro-mechanical coupling factor K² is small, a passband as a band-pass filter becomes narrow. Therefore, as described above, the surface acoustic wave resonator according to the present embodiment is suitable for use as, for example, a band rejection filter.

Furthermore, as shown in a bottommost graph in FIG. 19, TCF of the surface acoustic wave resonator according to the present embodiment is small, at −11.6 ppm/° C., and is preferable.

### <Analysis of Resonance Characteristics by Simulation>

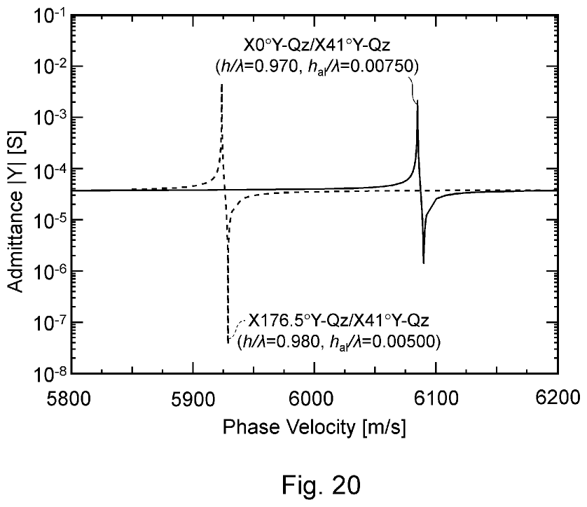

Next, a result of an analysis of resonance characteristics of the surface acoustic wave resonator according to the present embodiment by a simulation will be described with reference to FIG. 20. FIG. 20 is a graph showing a result of an analysis of resonance characteristics of the surface acoustic wave resonator according to the third embodiment by a simulation. FIG. 20 corresponds to FIG. 4 in the first embodiment and, in FIG. 20, an axis of abscissa represents a phase velocity (m/s) and an axis of ordinate represents admittance (S).

In FIG. 20, a result of an analysis of a surface acoustic wave resonator in which an X-cut 0° Y-propagation quartz-crystal substrate QS2 is bonded over an X-cut 41° Y-propagation quartz-crystal substrate QS1 is indicated by a solid line. This configuration is denoted as X0° Y-Qz/X41° Y-Qz in FIG. 20.

In addition, in FIG. 20, a result of an analysis of a surface acoustic wave resonator in which an X-cut 176.5° Y-propagation quartz-crystal substrate QS2 is bonded over an X-cut 41° Y-propagation quartz-crystal substrate QS1 is indicated by a dashed line. In other words, this is a configuration in which the propagation angle ψ2 of the quartz-crystal substrate QS2 deviates from a 0° Y-propagation by 3.5° in a negative direction. This configuration is denoted as X176.5° Y-Qz/X41° Y-Qz in FIG. 20.

With respect to the surface acoustic wave resonator described above, a finite element method (FEM) analysis of resonance characteristics was performed using analysis software Femtet manufactured by Murata Software Co., Ltd. The wavelength λ (=2 p) of a surface acoustic wave was set to 8 μm and the thickness of the support substrate was set to 10 λ. In addition, as shown in FIG. 20, the normalized plate thickness h/λ of the X-cut 0° Y-propagation quartz-crystal substrate QS2 was set to 0.970 at which propagation attenuation decreases in FIG. 19. With respect to the X-cut 176.5° Y-propagation quartz-crystal substrate QS2, the normalized plate thickness h/λ was set to 0.980 at which propagation attenuation decreases in FIG. 19.

It was assumed that the IDT electrode IDT shown in FIG. 1 is made of an aluminum (Al) film and has an infinite periodic structure. In addition, a perfect matched layer (PML) was set on a bottom surface of the IDT electrode. The metallization ratio w/p was set to 0.5. In addition, a sinusoidal AC voltage of ±1 V was applied to the IDT electrode IDT. Dielectric loss and mechanical loss of each material were not taken into consideration. With respect to the X-cut 0° Y-propagation quartz-crystal substrate QS2, the film thickness of the IDT electrode IDT was set to 0.06 μm (=0.00750 λ). With respect to the X-cut 176.5° Y-propagation quartz-crystal substrate QS2, the film thickness of the IDT electrode IDT was set to 0.04 μm (=0.00500 λ).

With the surface acoustic wave resonator of X0° Y-Qz/X41° Y-Qz indicated by a solid line in FIG. 20, an admittance ratio was 63 dB, a resonant quality factor was 34600, and an antiresonant quality factor was 16200, which were all high values. Moreover, the specific bandwidth was 0.082%.

With the surface acoustic wave resonator of X176.5° Y-Qz/X41° Y-Qz indicated by a dashed line in FIG. 20, an admittance ratio was 122 dB, a resonant quality factor was 185000, and an antiresonant quality factor was 741000, which were all high values. Moreover, the specific bandwidth was 0.086%.

As described above, in a surface acoustic wave resonator in which the X-cut 0° Y-propagation quartz-crystal substrate QS2 having a normalized plate thickness h/λ of approximately 1.0 is bonded over the X-cut 41° Y-propagation quartz-crystal substrate QS1, superior resonance characteristics which cannot be obtained with a stand-alone quartz-crystal substrate are obtained.

In addition, by giving the quartz-crystal substrate QS2 the propagation angle ψ2 of 176.5° so that the quartz-crystal substrate QS2 is deviated from 0° Y-propagation by 3.5° in the negative direction, even more superior resonance characteristics are obtained.

### <Allowable Range of Euler Angles (φ1, θ1, ψ1) of Quartz-crystal Substrate QS1>

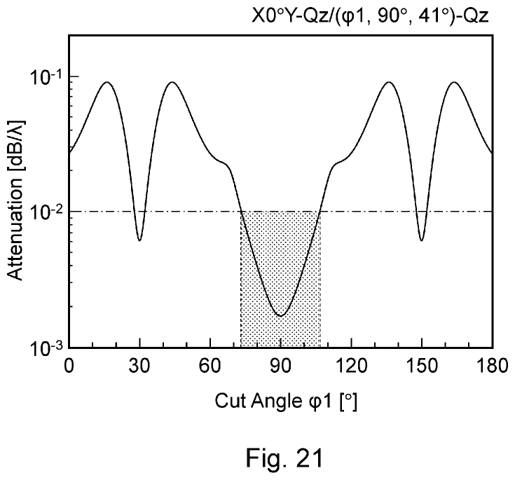

Next, an allowable range of the Euler angles (φ1, θ1, ψ1) of the quartz-crystal substrate QS1 will be explained with reference to FIGS. 21 to 23.

FIG. 21 is a graph showing a result of a theoretical analysis of cut angle φ1 dependence of the quartz-crystal substrate QS1 with respect to propagation attenuation of the surface acoustic wave resonator according to the third embodiment.

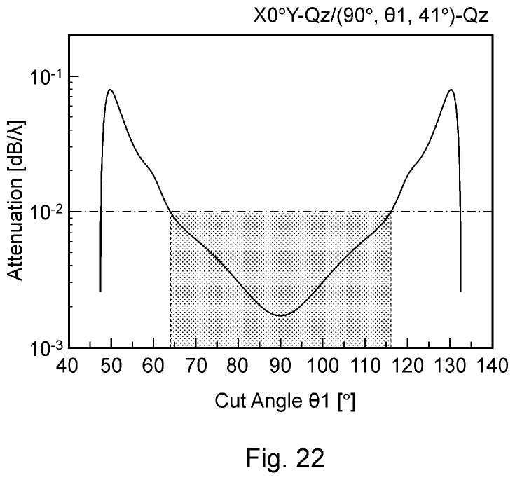

FIG. 22 is a graph showing a result of a theoretical analysis of cut angle θ1 dependence of the quartz-crystal substrate QS1 with respect to propagation attenuation of the surface acoustic wave resonator according to the third embodiment.

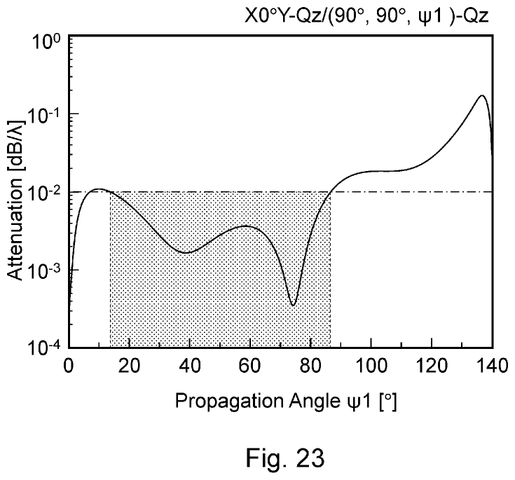

FIG. 23 is a graph showing a result of a theoretical analysis of propagation angle ψ1 dependence of the quartz-crystal substrate QS1 with respect to propagation attenuation of the surface acoustic wave resonator according to the third embodiment.

In FIGS. 21 to 23, the quartz-crystal substrate QS2 is an X-cut 0° Y-propagation quartz-crystal substrate. The normalized plate thickness h/λ of the quartz-crystal substrate QS2 was respectively set to 0.990 in FIG. 19 at which propagation attenuation is locally minimized.

As shown in FIG. 21, when changing the cut angle φ1 of the quartz-crystal substrate QS1, the cut angle θ1 was fixed to 90° and the propagation angle ψ1 was fixed to 41°.

As shown in FIG. 22, when changing the cut angle θ1 of the quartz-crystal substrate QS1, the cut angle φ1 was fixed to 90° and the propagation angle ψ1 was fixed to 41°.

As shown in FIG. 23, when changing the propagation angle ψ1 of the quartz-crystal substrate QS1, the cut angle φ1 was fixed to 90° and the cut angle θ1 was fixed to 90°.

As indicated by dot-hatching in FIG. 21, in the surface acoustic wave resonator according to the present embodiment, propagation attenuation is 0.01 dB/λ or less when the cut angle φ1 of the quartz-crystal substrate QS1 ranges from 73.5 to 106.5°. Therefore, in the surface acoustic wave resonator according to the present embodiment, the cut angle φ1 of the quartz-crystal substrate QS1 is configured so as to satisfy 74°≤φ1≤107°. The cut angle φ1 of the quartz-crystal substrate QS1 preferably satisfies 80°≤φ1≤100° and more preferably satisfies 85°≤φ1≤95°.

As indicated by dot-hatching in FIG. 22, in the surface acoustic wave resonator according to the present embodiment, propagation attenuation is 0.01 dB/λ or less when the cut angle θ1 of the quartz-crystal substrate QS1 ranges from 64.0 to 116.0°. Therefore, in the surface acoustic wave resonator according to the present embodiment, the cut angle θ1 of the quartz-crystal substrate QS1 is configured so as to satisfy 64°≤θ1≤116°. The cut angle θ1 preferably satisfies 70°≤θ1≤110°, more preferably satisfies 80°≤θ1≤100°, and even more preferably satisfies 85°≤θ1≤95°.

Note that a solution is only obtained in a range of a curved line shown in FIG. 22.

As indicated by dot-hatching in FIG. 23, in the surface acoustic wave resonator according to the present embodiment, propagation attenuation is 0.01 dB/λ or less when the propagation angle ψ1 of the quartz-crystal substrate QS1 ranges from 13.8 to 86.6°. Therefore, in the surface acoustic wave resonator according to the present embodiment, the propagation angle ψ1 of the quartz-crystal substrate QS1 is configured so as to satisfy 14°≤ψ1≤87°. The propagation angle ψ1 of the quartz-crystal substrate QS1 preferably satisfies 21°≤ψ1≤61°, more preferably satisfies 31°≤ψ1≤51°, and even more preferably satisfies 36°≤ψ1≤46°.

### <Allowable Range of Euler Angles (φ2, θ2, ψ2) of Quartz-crystal Substrate QS2>

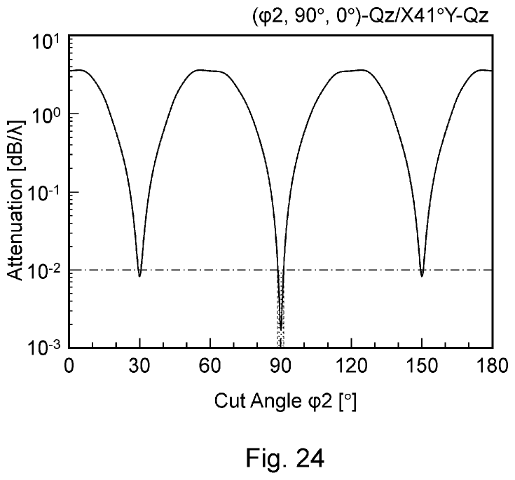

Next, an allowable range of the Euler angles (φ2, θ2, ψ2) of the quartz-crystal substrate QS2 will be explained with reference to FIGS. 24 to 26.

FIG. 24 is a graph showing a result of a theoretical analysis of cut angle φ2 dependence of the quartz-crystal substrate QS2 with respect to propagation attenuation of the surface acoustic wave resonator according to the third embodiment.

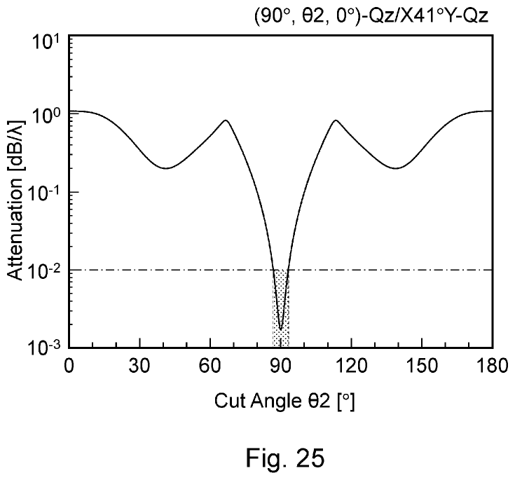

FIG. 25 is a graph showing a result of a theoretical analysis of cut angle θ2 dependence of the quartz-crystal substrate QS2 with respect to propagation attenuation of the surface acoustic wave resonator according to the third embodiment.

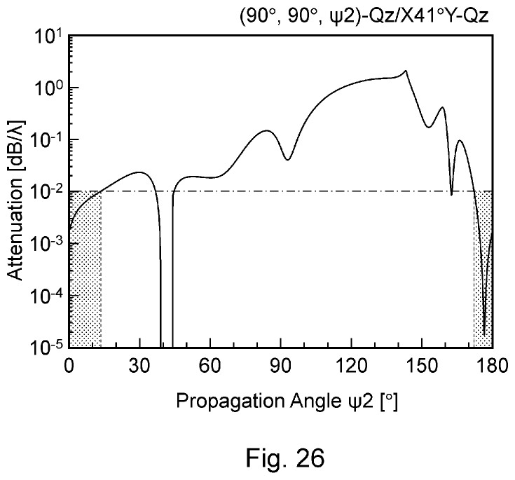

FIG. 26 is a graph showing a result of a theoretical analysis of propagation angle ψ2 dependence of the quartz-crystal substrate QS2 with respect to propagation attenuation of the surface acoustic wave resonator according to the third embodiment.

In FIGS. 24 to 26, the quartz-crystal substrate QS1 is an X-cut 41° Y-propagation quartz-crystal substrate. The normalized plate thickness h/λ of the quartz-crystal substrate QS2 was respectively set to 0.990 in FIG. 19 at which propagation attenuation is locally minimized.

As shown in FIG. 24, when changing the cut angle φ2 of the quartz-crystal substrate QS2, the cut angle θ2 was fixed to 90° and the propagation angle ψ2 was fixed to 0°.

As shown in FIG. 25, when changing the cut angle θ2 of the quartz-crystal substrate QS2, the cut angle φ2 was fixed to 90° and the propagation angle ψ2 was fixed to 0°.

As shown in FIG. 26, when changing the propagation angle ψ2 of the quartz-crystal substrate QS2, the cut angle φ2 was fixed to 90° and the cut angle θ2 was fixed to 90°.

As indicated by dot-hatching in FIG. 24, in the surface acoustic wave resonator according to the present embodiment, propagation attenuation is 0.01 dB/λ or less when the cut angle φ2 of the quartz-crystal substrate QS2 ranges from 88.8 to 91.2°. Therefore, in the surface acoustic wave resonator according to the present embodiment, the cut angle φ2 of the quartz-crystal substrate QS2 is configured so as to satisfy 89°≤φ2≤91°.

As indicated by dot-hatching in FIG. 25, in the surface acoustic wave resonator according to the present embodiment, propagation attenuation is 0.01 dB/λ or less when the cut angle θ2 of the quartz-crystal substrate QS2 ranges from 86.9 to 93.1°. Therefore, in the surface acoustic wave resonator according to the present embodiment, the cut angle θ2 of the quartz-crystal substrate QS2 is configured so as to satisfy 87°≤θ2≤93°. The cut angle θ2 preferably satisfies 88°≤θ2≤92° and more preferably satisfies 89°≤θ2≤91°.

As indicated by dot-hatching in FIG. 26, in the surface acoustic wave resonator according to the present embodiment, propagation attenuation is 0.01 dB/λ or less when the propagation angle ψ2 of the quartz-crystal substrate QS2 ranges from 0 to 13.2° and 172.2° or more and less than 180°. Therefore, in the surface acoustic wave resonator according to the present embodiment, the propagation angle ψ2 of the quartz-crystal substrate QS2 is configured so as to satisfy 0°≤ψ2≤13° or 172°≤ψ2≤180°. In addition, since a local minimum value is given when propagation angle ψ2=176.5°, the propagation angle ψ2 more preferably satisfies 174°≤ψ2≤179°.

The configuration is otherwise the same as the surface acoustic wave resonator according to the first embodiment.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A bonded substrate, comprising:
φ1 a first quartz-crystal substrate; and
φ1 a second quartz-crystal substrate bonded over the first quartz-crystal substrate, wherein
Euler angles (φ1, θ1, ψ1) of the first quartz-crystal substrate satisfy 0°≤φ1≤2°, 123°≤θ1≤128°, and 31°≤ψ1≤44°,
Euler angles (φ2, θ2, ψ2) of the second quartz-crystal substrate satisfy 83°≤φ2≤95°, 82°≤θ2≤95°, and 159°≤ψ2≤161°, and
a thickness of the second quartz-crystal substrate is 0.17 to 0.19 times a wavelength of a longitudinal leaky surface acoustic wave which propagates across a surface of the second quartz-crystal substrate.

2. A bonded substrate, comprising:
φ1 a first quartz-crystal substrate; and
φ1 a second quartz-crystal substrate bonded over the first quartz-crystal substrate, wherein
Euler angles (φ1, θ1, ψ1) of the first quartz-crystal substrate satisfy 83°≤φ1≤97°, 80°≤θ1≤100°, and 30°≤ψ1≤59°,
Euler angles (φ2, θ2, ψ2) of the second quartz-crystal substrate satisfy 88°≤φ2≤92°, 88°≤θ2≤92°, and 53°≤ψ2≤63°, and
a thickness of the second quartz-crystal substrate is 0.33 to 0.46 times a wavelength of a longitudinal leaky surface acoustic wave which propagates across a surface of the second quartz-crystal substrate.

3. A bonded substrate, comprising:
φ1 a first quartz-crystal substrate; and
φ1 a second quartz-crystal substrate bonded over the first quartz-crystal substrate, wherein
Euler angles (φ1, θ1, ψ1) of the first quartz-crystal substrate satisfy 74°≤φ1≤107°, 64°≤θ1≤116°, and 14°≤ψ1≤87°,
Euler angles (φ2, θ2, ψ2) of the second quartz-crystal substrate satisfy 89°≤φ2≤91°, 87°≤θ2≤93°, and 0°≤ψ2≤13° or 172°≤ψ2≤180°, and
a thickness of the second quartz-crystal substrate is 0.94 to 1.04 times a wavelength of a longitudinal leaky surface acoustic wave which propagates across a surface of the second quartz-crystal substrate.

4. The bonded substrate according to claim 1, wherein propagation attenuation per unit wavelength of the longitudinal leaky surface acoustic wave is 0.01 dB or less.

5. The bonded substrate according to claim 1, wherein the first quartz-crystal substrate and the second quartz-crystal substrate are bonded so as to come into direct contact with each other.

6. The bonded substrate according to claim 2, wherein propagation attenuation per unit wavelength of the longitudinal leaky surface acoustic wave is 0.01 dB or less.

7. The bonded substrate according to claim 2, wherein the first quartz-crystal substrate and the second quartz-crystal substrate are bonded so as to come into direct contact with each other.

8. The bonded substrate according to claim 3, wherein propagation attenuation per unit wavelength of the longitudinal leaky surface acoustic wave is 0.01 dB or less.

9. The bonded substrate according to claim 3, wherein the first quartz-crystal substrate and the second quartz-crystal substrate are bonded so as to come into direct contact with each other.
